(19) United States
(12) Patent Application Publication
(10) Pub. No.: US 2014/0261664 A1
(43) Pub. Date: Sep. 18, 2014

(54) Photovoltaic Cell Having An Antireflective Coating

(71) Applicant: PPG Industries Ohio, Inc., Cleveland, OH (US)

(72) Inventors: Adam D. Polcyn, Pittsburgh, PA (US); Ashtosh Ganjoo, Allison Park, PA (US); James W. McCamy, Export, PA (US)

(73) Assignee: PPG Industries Ohio, Inc., Cleveland, OH (US)

(21) Appl. No.: 14/200,045

(22) Filed: Mar. 7, 2014

Related U.S. Application Data
(60) Provisional application No. 61/777,329, filed on Mar. 12, 2013.

(51) Int. Cl. H01L 31/0216

(52) U.S. Cl. CPC H01L 31/02168
USPC 136/256

(57) ABSTRACT

The present invention relates to a photovoltaic cell that includes a transparent substrate that has a first surface and a second surface. A transparent conductive oxide coating resides over the second surface of the transparent substrate. A photovoltaic coating resides over the transparent conductive oxide coating. The photovoltaic cell also includes an antireflective coating that resides over the first surface of the transparent substrate. The antireflective coating includes, in order from the first surface of the transparent substrate: a first layer that includes one or more metal oxides, for example, zinc stannate; a second layer that includes one or more metal oxides, for example, silica and alumina; a third layer that includes one or more metal oxides, for example, zinc stannate; and a fourth layer that includes one or more metal oxides, for example, silica.

### CROSS REFERENCE TO RELATED APPLICATION

This application claims priority to U.S. Provisional Application No. 61/777,329, filed Mar. 12, 2013, herein incorporated by reference in its entirety.

### BACKGROUND OF THE INVENTION

1. Field of the Invention

The present invention relates to a photovoltaic cell that includes a transparent substrate having a first surface with an antireflective coating thereover, a second surface with a transparent conductive oxide coating thereover, and a photovoltaic coating over the transparent conductive oxide coating.

2. Technical Considerations

Photovoltaic cells, such as solar cells, typically include a transparent substrate having a forward surface that faces a source of radiation, such the sun, and a rear surface. The following sequence of layers are typically provided on and extend away from the rear surface of the transparent substrate: a top electrode, a window layer, an absorber layer, a back electrode, and a back support. In addition to providing support, the transparent substrate protects the various layers that are stacked on the rear surface thereof from damage that can result from, for example, humidity and mechanical impacts.

The electrical efficiency of a solar cell depends in part on the amount of incident radiation that actually passes down through the stack of layers on the rear surface of the transparent substrate. Typically, some percentage of incident radiation is reflected from or at the forward surface of the transparent substrate. When incident radiation is reflected at the forward surface, the amount of radiation available to pass down through the rear stack of layers is reduced, and correspondingly the electrical efficiency of the solar cell is reduced.

It would be desirable to develop photovoltaic cells that are subject to reduced or minimal reflection of incident radiation associated with the transparent substrates thereof. It would be further desirable that such newly developed photovoltaic cells maintain such reduced or minimal reflection of incident actinic radiation under operating conditions, such as when exposed to weather and abrasion.

### SUMMARY

In accordance with the present invention, there is provided a photovoltaic cell that includes: (a) a transparent substrate comprising a first surface and a second surface, in which the first surface and the second surface are opposed from each other; (b) a transparent conductive oxide coating residing over the second surface of the transparent substrate; (c) a photovoltaic coating residing over the transparent conductive oxide coating, in which the transparent conductive oxide coating is interposed between the second surface of the transparent substrate and the photovoltaic coating; and (d) an antireflective coating over the first surface of the transparent substrate. The antireflective coating comprises: (i) a first layer comprising a metal oxide selected from an oxide of zinc, an oxide of zirconium, an oxide of tin, combinations of two or more thereof, and metal alloy oxides of two or more thereof, in which the first layer resides over the first major surface of the transparent substrate; (ii) a second layer comprising silica and optionally alumina, in which the second layer resides over the first layer; (iii) a third layer comprising a metal oxide selected from an oxide of zinc, an oxide of zirconium, an oxide of tin, combinations of two or more thereof, and metal alloy oxides of two or more thereof, in which the third layer resides over the second layer; and (iv) a fourth layer comprising silica and optionally alumina, in which the fourth layer resides over the third layer.

### BRIEF DESCRIPTION OF THE DRAWINGS

FIG. 1 is a representative sectional view of a photovoltaic cell according to the present invention;

FIG. 2 is a representative sectional view of further photovoltaic cell according to the present invention; and

FIG. 3 is a representative sectional schematic view of a photovoltaic module that includes two photovoltaic cells of the present invention.

In FIGS. 1-3, which are not to scale, like reference characters designate the same components and structural features.

### DETAILED DESCRIPTION OF THE INVENTION

As used herein, spatial or directional terms, such as “left”, “right”, “inner”, “outer”, “above”, “below”, and the like, relate to the invention as it is shown in the drawing figures. However, it is to be understood that the invention can assume various alternative orientations and, accordingly, such terms are not to be considered as limiting.

Other than in the operating examples (if any), or where otherwise indicated, all numbers expressing quantities of ingredients, reaction conditions, processing parameters, physical characteristics, dimensions, and the like used in the specification and claims are to be under stood as modified in all instances by the term “about.” Accordingly, unless indicated to the contrary, the numerical values set forth in the following specification and claims can vary depending upon the desired properties sought to be obtained by the present invention.

Additionally, at the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like.

As used herein, the terms “formed over,” “deposited over,” “residing over,” or “provided over” mean formed, deposited, or provided on but not necessarily in direct (or abutting) contact with the surface. For example, a coating layer “formed over” or “residing over” a substrate, or a surface of a substrate, does not preclude the presence of one or more other coating layers or films of the same or different composition located between the formed (or identified) coating layer and the substrate.

As used herein the term “interposed” and related terms, such as “interposed between” means residing or positioned between, but not necessarily in direct (or abutting) contact with one or both elements, such as layers, that the indentified element, such as a layer, is interposed between.

The term “visible region” and related terms, such as “visible light” as used herein means electromagnetic radiation having a wavelength in the range of 380 nm to 780 nm.

As used herein, the term “actinic radiation” means electromagnetic radiation that is capable of causing a response in a material, such as, but not limited to, causing a photovoltaic coating to produce electricity.

The term “infrared region” and related terms, such as “infrared radiation” as used herein mean electromagnetic radiation having a wavelength in the range of greater than 780 nm to 100,000 nm.

The term “ultraviolet region” and related terms, such as “ultraviolet radiation” mean electromagnetic energy having a wavelength in the range of 100 nm to less than 380 nm.

All documents, such as but not limited to issued patents and patent applications, referred to herein are to be considered to be “incorporated by reference” in their entirety.

As used herein, the articles “a,” “an,” and “the” include plural referents unless otherwise expressly and unequivocally limited to one referent.

As used herein the term “transparent” means having a transmission of greater than 0% up to 100% in a desired wavelength range, such as visible light. As used herein the term “translucent” means allowing electromagnetic radiation, such as visible light, to be transmitted but diffusing or scattering this electromagnetic radiation. As used herein the term “opaque” means having a transmission of substantially 0%, such as 0%, in a desired wavelength range, such as visible light.

In accordance with some embodiments and with reference to FIG. 1 of the drawings, the photovoltaic cell 1 of the present invention includes a transparent substrate 11 that includes a first surface 14 and a second surface 17 that are opposed relative to each other. First surface 14 of transparent substrate 11 can be in facing opposition with (or faces) a source of actinic radiation 47. The source of actinic radiation can be selected from artificial sources of electromagnetic radiation and/or natural sources of electromagnetic radiation that result in the production of electricity when passing through the photovoltaic cells of the present invention. Examples of artificial sources of electromagnetic radiation from which the source of actinic radiation can be selected include, but are not limited to, electric lights, such as incandescent lights, fluorescent lights, light emitting diodes, and noble gas lights, such as xenon lights. Examples of natural sources of electromagnetic radiation include, but are not limited to, direct solar radiation, reflected solar radiation, and/or magnified solar radiation.

Photovoltaic cell 1 further includes a transparent conductive oxide coating 20 that resides (or is positioned) over the second surface 17 of transparent substrate 11. The transparent conductive oxide coating 20 can abut second surface 17 of transparent substrate 11.

Photovoltaic cell 1 further includes a photovoltaic coating 23 that resides over the transparent conductive oxide coating 20, such that transparent conductive oxide coating 20 is interposed between second surface 17 of transparent substrate 11 and photovoltaic coating 23. Photovoltaic coating 23 can abut transparent conductive oxide coating 20.

The photovoltaic cells of the present invention can further include a back electrode that is positioned (or resides) over the photovoltaic coating. With non-limiting reference to FIG. 1, photovoltaic cell 1 includes a back electrode 26 that is positioned over photovoltaic coating 23. The back electrode 26 and photovoltaic coating 23 can abut each other. The back electrode of the photovoltaic cells of the present invention is described in further detail below.

The photovoltaic cells of the present invention can additionally include a back substrate that is positioned (or resides) over the back electrode. With non-limiting reference to FIG. 1, photovoltaic cell 1 further includes a back substrate 29 that is positioned over back electrode 26. The back substrate 29 and back electrode 26 can abut each other. The back substrate of the photovoltaic cells of the present invention is described in further detail below.

The photovoltaic cells of the present invention include an antireflective coating that resides over the first surface of the transparent substrate. With non-limiting reference to FIG. 1, photovoltaic cell 1 further includes an antireflective coating 32 that is positioned over first surface 14 of transparent substrate 11. Antireflective coating 32 includes a first layer 35 that includes a metal oxide selected from an oxide of zinc, an oxide of zirconium, an oxide of tin, combinations of two or more thereof, and metal alloy oxides of two or more thereof. First layer 35 resides over first surface 14 of transparent substrate 11. The first layer 35 and first surface 14 can abut each other.

With further reference to FIG. 1, antireflective coating 32 includes a second layer 38 that includes silica and optionally alumina. Second layer 38 resides over first layer 35 of antireflective coating 32. The second layer 38 and first layer 35, of antireflective coating 32, can abut each other.

Antireflective coating 32 includes, with further reference to FIG. 1, a third layer 41 that includes a metal oxide selected from an oxide of zinc, an oxide of zirconium, an oxide of tin, combinations of two or more thereof, and metal alloy oxides of two or more thereof. Third layer 41 resides over second layer 38 of antireflective coating 32. Third layer 41 and second layer 38 of antireflective coating 32 can abut each other.

Antireflective coating 32 includes, with further reference to FIG. 1, a fourth layer 44 that includes silica and optionally alumina. Fourth layer 44 resides over third layer 41 of antireflective coating 32. Fourth layer 44 and third layer 41 of antireflective coating 32 can abut each other.

The transparent substrate of the photovoltaic cells of the present invention can include, or be fabricated from, a material such as, but not limited to: organic polymers, such as thermoplastic, thermoset, or elastomeric polymeric materials; glasses, such as inorganic glasses; ceramics; and combinations, composites, or mixtures of two or more thereof. Further examples of suitable materials include, but are not limited to, plastic substrates (such as acrylic polymers, such as polyacrylates; polyalkylmethacrylates, such as polymethylmethacrylates, polyethylmethacrylates, polypropylmethacrylates, and the like; polyurethanes; polycarbonates; polyalkylterephthalates, such as polyethyleneterephthalate (PET), polypropyleneterephthalates, polybutyleneterephthalates, and the like; polysiloxane-containing polymers; or copolymers of any monomers for preparing these, or any mixtures thereof); ceramic substrates; glass substrates; or mixtures or combinations of any of the above.

The transparent substrate can include conventional soda-lime-silicate glass, borosilicate glass, or leaded glass. The glass can be clear glass. By “clear glass” is meant non-tinted or non-colored glass. Alternatively, the glass can be tinted or otherwise colored glass. The glass can be annealed or heat-treated glass. As used herein, the term “heat treated” means tempered, bent, heat strengthened, or laminated. The glass can be of any type, such as conventional float glass, and can be of any composition having any optical properties, e.g., any value of visible transmission, ultraviolet transmission, infrared transmission, and/or total solar energy transmission. The transparent substrate can be selected from, for example, clear float glass or can be tinted or colored glass. Although not limiting to the invention, examples of glass suitable for the transparent substrate are described in U.S. Pat. Nos. 4,746,347; 4,792,536; 5,030,593; 5,030,594; 5,240,886; 5,385,872; and 5,393,593. The transparent substrate can be of any desired dimensions, e.g., length, width, shape, or thickness. With some embodiments, the transparent substrate can be greater than 0 up to 10 mm thick, such as 1 mm to 10 mm thick, or 1 mm to 5 mm thick, or less than 4 mm thick, such as, 3 mm to 3.5 mm thick, or 3.2 mm thick. Additionally, the transparent substrate can be of any desired shape, such as flat, curved, parabolic-shaped, or the like, with some embodiments.

The transparent substrate can have a high visible light transmission at a reference wavelength of 550 nanometers (nm) and a reference thickness of 3.2 mm. By “high visible light transmission” is meant visible light transmission at 550 nm of greater than or equal to 85%, such as greater than or equal to 87%, such as greater than or equal to 90%, such as greater than or equal to 91%, such as greater than or equal to 92%, such as greater than or equal to 93%, such as greater than or equal to 95%, at 3.2 mm reference thickness for the transparent substrate. Further non-limiting examples of glass from which the transparent substrate can be selected include, but are not limited to, those disclosed in U.S. Pat. Nos. 5,030,593 and 5,030,594. Non-limiting examples of glass from which the transparent substrate can be selected include, but are not limited to, Starphire®, Solarphire®, Solarphire® PV, Solargreen®, Solextra®, GL-20®, GL35™, Solarbronze®, CLEAR, and Solargray® glass, all commercially available from PPG Industries Inc. of Pittsburgh, Pa.

The first and third layers of the antireflective coating each independently include a metal oxide selected from an oxide of zinc, an oxide of zirconium, an oxide of tin, combinations (or mixtures) of two or more thereof, and metal alloy oxides of two or more thereof. The first and third layers of the antireflective coating can each independently include an oxide of zinc, an oxide of tin, combinations thereof, and metal alloy oxides thereof. The first and third layers of the antireflective coating can each independently include a zinc/tin alloy oxide or a zinc/tin oxide mixture (or combination). The zinc/tin alloy oxides can be obtained from magnetron sputtering vacuum deposition from a cathode of zinc and tin that can include zinc in an amount of 10 wt. % to 90 wt. %, and tin in an amount of 90 wt. % to 10 wt. %, in which the weight percents are in each case based on total weight of zinc and tin present in the cathode. The first and third layers of the antireflective coating can each independently include a zinc/tin alloy oxide that includes zinc in an amount of 10 wt. % to 90 wt. %, and tin in an amount of 90 wt. % to 10 wt. %, in which the weight percents are in each case based on total weight of zinc and tin present in the layer.

With some embodiments, the first and third layers of the antireflective coating each independently include a metal alloy oxide of zinc and tin in the form of zinc stannate. As used herein, the term “zinc stannate” means a material or composition represented by the following Formula (I):

Zn_{X}Sn_{1-X}O_{2-X} Formula (I)

With reference to Formula (I) subscript x varies in the range of greater than 0 to less than 1. For instance, subscript x can be greater than 0 and can be any fraction or decimal between greater than 0 to less than 1. For purposes of non-limiting illustration, where x=2/3, Formula 1 is Zn_{2/3}Sn_{1/3}O_{4/3}, which is described as “Zn₂SnO₄” with some embodiments. The first and third layers of the antireflective coating, with some embodiments, each independently include zinc stannate in one or more forms as represented by Formula (I).

The second and fourth layers of the antireflective coating each independently include silica and optionally alumina. The second and fourth layers of the antireflective coating can each independently include silica in an amount of greater than 0 wt. % to less than or equal to 100 wt. %. The second and fourth layers of the antireflective coating can each independently include: 1 wt. % to 99 wt. % alumina and 99 wt. % to 1 wt. % silica; or 5 wt. % to 95 wt. % alumina and 95 wt. % to 5 wt. % silica; or 10 wt. % to 90 wt. % alumina and 90 wt. % to 10 wt. % silica; or 15 wt. % to 90 wt. % alumina and 85 wt. % to 10 wt. % silica; or 50 wt. % to 75 wt. % alumina and 50 wt. % to 25 wt. % silica; or 50 wt. % to 70 wt. % alumina and 50 wt. % to 30 wt. % silica; or 70 wt. % to 90 wt. % alumina and 30 wt. % to 10 wt. % silica; or 75 wt. % to 85 wt. % alumina and 25 wt. % to 15 wt. % of silica, such as 88 wt. % alumina and 12 wt. % silica; or 65 wt. % to 75 wt. % alumina and 35 wt. % to 25 wt. % silica, such as 70 wt. % alumina and 30 wt. % silica; or 60 wt. % to less than 75 wt. % alumina and greater than 25 wt. % to 40 wt. % silica. In accordance with some embodiments, the second and fourth layers of the antireflective coating each independently include 40 wt. % to 15 wt. % alumina and 60 wt. % to 85 wt. % silica, such as 85 wt. % silica and 15 wt. % alumina.

The second and fourth layers of the antireflective coating can each independently include a combination of silica and alumina. The second and fourth layers of the antireflective coating can each be independently sputtered from: two cathodes, such as one composed of silicon and one composed of aluminum; or from a single cathode containing both silicon and aluminum. The combination of silica and alumina in the second and fourth layers of the antireflective coating can, with some embodiments, be in each case independently represented by the following Formula (II),

Si_{y}Al_{1-y}O_{1.5+y/2}, Formula (II)

With reference to Formula (II), subscript y can vary from greater than 0 to less than 1.

In an exemplary antireflective coating of the photovoltaic cell, the first layer comprises zinc stannate; the second layer comprises silica and aluminum oxide; the third layer comprises zinc stannate; and the fourth layer comprises silica.

In some further examples of the antireflective coating of the photovoltaic cell, the first layer consists of zinc stannate; the second layer consists of silica and aluminum oxide; the third layer consists of zinc stannate; and the fourth layer consists of silica.

The second layer of the antireflective coating of the photovoltaic cell can include silica in an amount of from 70 percent by weight to 95 percent by weight, and aluminum oxide in an amount of from 5 percent by weight to 30 percent by weight, in each case based on total weight of the third layer.

The second layer of the antireflective coating of the photovoltaic cell, if desired, consists of silica in an amount of from 70 percent by weight to 95 percent by weight, and aluminum oxide in an amount of from 5 percent by weight to 30 percent by weight, in each case based on total weight of the third layer.

With the antireflective coating of the photovoltaic cell, and in accordance with some exemplary embodiments: the first layer has a thickness of from 15 nm to 22 nm, such as 18.5 nm; the second layer has a thickness of from 22 nm to 33 nm, such as 27 nm; the third layer has a thickness of from 95 nm to 143 nm, such as 119 nm; and the fourth layer has a thickness of from 75 nm to 115 nm, such as 93 nm.

In accordance with some further embodiments of the present invention, with the antireflective coating of the photovoltaic cell: a ratio of thickness of the second layer to thickness of the first layer is from 1:1 to 2:1, such as 1.46:1; a ratio of thickness of the third layer to thickness of the first layer is from 6:1 to 7:1, such as 6.43:1; and a ratio of thickness of the fourth layer to thickness of the first layer is from 4.5:1 to 5.5:1, such as 5.14:1.

The antireflective coating of the photovoltaic cell of the present invention can be formed from sputtering vacuum deposition. With some further embodiments, each layer of the antireflective coating is independently formed from sputtering vacuum deposition. The antireflective coating of the photovoltaic cell of the present invention can be formed from magnetron sputtering vacuum deposition. With some additional embodiments, each layer of the antireflective coating is independently formed from magnetron sputtering vacuum deposition. The sputtering vacuum deposition, such as magnetron sputtering vacuum deposition, of each layer of the antireflective coating can be conducted using one or more cathodes (or targets), such as described previously herein.

The antireflective coating of the photovoltaic cells of the present invention provides desirable physical properties including, but not limited to: humidity resistance, such as passing humidity testing at 85° C. for 1 year at 85% relative humidity, in accordance with the requirements of IEC 61215; freeze thaw resistance, such as passing 60 freeze-thaw cycles; sulfuric acid resistance, such as determined in accordance with EN 1096-2; and abrasion resistance, such as determined in accordance with EN 1096-2.

The transparent conductive oxide coating of the photovoltaic cell of the present invention can include at least one layer, in which each layer of the transparent conductive oxide coating independently includes: at least one of an oxide, a nitride, a carbide, and an oxycarbide of silica; at least one of an oxide, a nitride, a carbide, and an oxycarbide of aluminum; at least one of an oxide, a nitride, a carbide, and an oxycarbide of zirconium; at least one of an oxide, a nitride, a carbide, and an oxycarbide of tin; at least one of an oxide, a nitride, a carbide, and an oxycarbide of indium; and combinations of two or more thereof.

With some embodiments, at least one layer of the transparent conductive oxide coating of the photovoltaic cell includes indium tin oxide and/or tin oxide.

The transparent conductive oxide coating of the photovoltaic cell can include: a first layer that includes indium tin oxide and/or tin oxide; and a second layer that includes tin oxide. The first layer that includes indium tin oxide and/or tin oxide, of the transparent conductive oxide coating can be interposed between the transparent substrate and the second layer that includes tin oxide. The first layer that includes indium tin oxide and/or tin oxide, of the transparent conductive oxide coating, abuts the second surface of the transparent substrate, and the second layer that includes tin oxide abuts the first layer that includes indium tin oxide and/or tin oxide, with some embodiments.

With non-limiting reference to FIG. 2 of the drawings, transparent conductive oxide layer 20, of photovoltaic cell 3, includes a first layer 50 and a second layer 53. First layer 50 is interposed between second layer 53 and second surface 17 of transparent substrate 11. The first layer 50 has a lower resistivity than second layer 53, and correspondingly second layer 53 has a higher resistivity than first layer 50. With some embodiments, first layer 50 includes indium tin oxide and/or tin oxide, and second layer 53 includes tin oxide. In accordance with some further embodiments, first layer 50 includes tin oxide, and second layer 53 includes tin oxide. First layer 50 abuts second surface 17 of transparent substrate 11, and first layer 50 and second layer 53 abut each other, with some embodiments. In accordance with some embodiments, first layer 50 of transparent conductive oxide layer 20 has a thickness of from 250 nanometers to 1250 nanometers, and second layer 53 of transparent conductive oxide layer 20 has a thickness of from 50 nanometers to 250 nanometers.

Each layer of the transparent conductive oxide layer can include one or more dopants. Examples of dopants include, but are not limited to, fluorine, antimony, nickel, aluminum, gallium, and/or boron.

The transparent conductive oxide coating can be formed by chemical vapor deposition methods. Each layer of the transparent conductive oxide coating can be independently formed by one or more chemical vapor deposition methods. Examples of chemical vapor deposition (CVD) methods that can be used include, but are not limited to, combustion CVD, plasma assisted CVD, remote plasma assisted CVD, and laser assisted CVD. The CVD process can, with some embodiments, be conducted using suitable precursor materials, such as monobutyltintrichloride, indium hydroxide, indium trichloride, indium carboxylates, such as indium benzoate, and trifluoroacetic acid for forming a fluorine dopant.

Each layer of the transparent conductive oxide layer can independently have a thickness of from 50 nanometers (nm) to 3000 nm, or from 100 nm to 2500 nm, or from 200 nm to 2000 nm, or any combination of these recited lower and upper values.

The photovoltaic coating of the photovoltaic cell of the present invention can include at least one layer that includes: cadmium telluride; cadmium sulfide; an alloy of copper and indium, that optionally further includes at least one of gallium, selenium, and sulfur; and combinations of two or more thereof. With some embodiments the alloy of copper and indium includes: gallium present in an amount of 0 to 50 percent by weight, based on total weight of the alloy; and a total of selenium and sulfur present in an amount of 0 to 50 percent by weight, based on total weight of the alloy, in which the weight ratio of selenium to sulfur is from 0:1 to 1:0. With some embodiments, the alloy of copper and indium is copper-indium-gallium-diselenide (CIGS).

Each layer of the photovoltaic coating can independently have a thickness of from 10 nanometers (nm) to 6000 nm, or from 50 nm to 5500 nm, or from 100 nm to 5000 nm, or any combination of these recited lower and upper values.

The photovoltaic coating can include a first layer that includes an n-type material, and a second layer including a p-type material. The first layer that includes the n-type material can be interposed between the transparent conductive oxide coating and the second layer that includes the p-type material. The first layer that includes the n-type material (of the photovoltaic coating) and the transparent conductive oxide coating abut each other, and the second layer that includes the p-type material and the first layer that includes the n-type material can abut each other.

For purposes of non-limiting illustration and with reference to FIG. 2, photovoltaic coating 23, of photovoltaic cell 3, includes a first layer 56 that includes an n-type material, and a second layer 59 that includes a p-type material. First layer 56 is interposed between transparent conductive oxide layer 20 and second layer 59. The first layer 56 can be interposed between second layer 53 of transparent conducive oxide coating 20 and second layer 59. First layer 56 of photovoltaic coating 23 can abut transparent conductive oxide coating 20 with some embodiments, and abuts second layer 53 of transparent conductive oxide coating 20, with some further embodiments. Second layer 59 and first layer 56 of photovoltaic coating 23 can abut each other. The first layer 56 can have a thickness of from 10 nanometers (nm) to 200 nm, and second layer 59 can have a thickness of from 300 nm to 4000 nm. In accordance with some further embodiments, first layer 56 is an optional layer, and has a thickness of from 0 nm to 200 nm.

In accordance with some embodiments, the first layer 53 that includes the n-type material of the photovoltaic coating 23 includes cadmium sulfide. The second layer 59 that includes the p-type material of the photovoltaic coating 23 can include cadmium telluride and/or copper-indium-gallium-diselenide (CIGS). With some embodiments, second layer 59 of photovoltaic coating 23 is composed substantially of cadmium telluride as the p-type material.

The photovoltaic coating can include at least one layer that includes silicon. The silicon of the photovoltaic coating can include amorphous silicon, monocrystalline silicon, polycrystalline silicon, and combinations of two or more thereof.

With some embodiments of the present invention, the photovoltaic coating can include at least one layer that includes polycrystalline silicon. For purposes of non-limiting illustration and with reference to FIG. 1, photovoltaic coating 23 is defined by a single layer that includes polycrystalline silicon.

The photovoltaic cells of the present invention can further include a back electrode, such as back electrode 26, as described previously herein. The back electrode can be fabricated from any material that can support (or carry) the photovoltaic electrical current generated by the photovoltaic cell. The he back electrode can be composed of one or more materials that can support (or carry) the photovoltaic electrical current generated by the photovoltaic cell with minimum resistive losses. The back electrode can include an electrically conductive material, such as, but not limited to, one or more electrically conductive metals, one or more electrically conductive metal oxides, one or more electrically conductive organic polymers, one or more electrically conductive carbon materials, one or more electrically conductive inorganic glasses, and combinations of two or more thereof.

With regard to the back electrode, examples of electrically conductive metals include, but are not limited to, aluminum, molybdenum, tungsten, vanadium, rhodium, niobium, chromium, tantalum, titanium, steel, nickel, platinum, silver, gold, an alloy of two or more thereof (such as KOVAR nickel-cobalt ferrous alloy), and/or combinations of two or more thereof. Examples of electrically conductive metal oxides that can be used with or to form the back electrode include, but are not limited to, tin oxide, titanium nitride, tin oxide, fluorine doped tin oxide, doped zinc oxide, aluminum doped zinc oxide, gallium doped zinc oxide, boron doped zinc oxide, indium-zinc oxide, and combinations of two or more thereof. Examples of electrically conductive carbon materials include, but are not limited to, metal-carbon black-filled oxides, graphite-carbon black-filled oxides, carbon black-carbon black-filled oxides, superconductive carbon black-filled oxides, and combinations of two or more thereof. Examples of electrically conductive organic polymers that can be used with or to form the back electrode include, but are not limited to, organic polymer compositions that include electrically conductive additives, such as electrically conductive pigments, such as electrically conductive carbon blacks and/or electrically conductive nano-carbon tubes, in amounts that are at least sufficient so as to render the organic polymer composition electrically conductive. Examples of electrically conductive inorganic glasses that can be used with or to form the back electrode include, but are not limited to, inorganic glasses that have electrically conductive metals incorporated therein and/or applied as one or more layers on at least one surface thereof, in which the electrically conductive metals are selected from those recited previously herein.

The photovoltaic cells of the present invention can further include a back substrate, such as back substrate 29, as described previously herein. The back substrate can be selected from one or more materials from which the transparent substrate, such as transparent substrate 11, is fabricated, as described previously herein. With some embodiments, the back substrate is fabricated from a non-transparent material, such as, but not limited to, non-transparent organic polymers, metals, metal alloys, non-transparent inorganic glass, and combinations of two or more thereof. Additional examples of organic polymers from which the back substrate can be fabricated, include, but are not limited to, urethane polymer, (meth)acrylic polymer, fluoropolymer, polybenzamidazole, polyimide, polytetrafluoroethylene, polyetheretherketone, polyamide-imide, polystyrene, cross-linked polystyrene, polyester, polycarbonate, polyolefin, such as polyethylene, polypropylene, and copolymers of ethylene and propylene, acrylonitrile-butadiene-styrene, polytetrafluoroethylene, nylon 6,6, cellulose acetate butyrate, cellulose acetate, rigid vinyl, plasticized vinyl, and combinations of two or more thereof. Examples of metals from which the back support can be fabricated with some embodiments include, but are not limited to: ferrous metals, such as stainless steel and/or iron; copper; aluminum; titanium; and combinations of two or more thereof.

The transparent conductive oxide coating 20, photovoltaic coating 23, and back electrode 26 can be formed on second surface 17 of transparent substrate 11, and back substrate 29 is held in contact with back electrode 26 by a frame that includes one or more clamps (not shown) and/or an adhesive (not shown) that is interposed between back substrate 29 and back electrode 26. The adhesive can include one or more layers, and can be selected from art-recognized adhesives, such as, but not limited to, silicon adhesives. Examples of adhesive materials include, but are not limited to, ethylene vinyl acetate (EVA), silicone, silicone gel, epoxy, polydimethyl siloxane (PDMS), RTV silicone rubber, polyvinyl butyral (PVB), thermoplastic polyurethane (TPU), polycarbonate, acrylic elastomers, a fluoropolymers, urethane materials, and combinations of two or more thereof. Additional examples of silicone adhesives include, but are not limited to, Q-type silicones, silsequioxanes, D-type silicones, and/or M-type silicones.

The transparent conductive oxide coating and the second surface of the transparent substrate can abut each other, and the photovoltaic cell of the present invention can be free of one or more layers, such as one or more adhesive layers, between the transparent conductive oxide coating and the second surface of the transparent substrate.

With some further embodiments, back electrode 26, photovoltaic coating 23, and transparent conductive oxide coating 20 are formed on back substrate 29, and transparent substrate 11 is held in contact with transparent conductive oxide coating 20 by a frame that includes one or more clamps (not shown) and/or an adhesive (not shown) that is interposed between second surface 17 of transparent substrate 11 and transparent conductive oxide coating 20. With such embodiments, the adhesive is selected such that it does not absorb (or only absorbs minimal) electromagnetic radiation that can be converted to electrical current by the photovoltaic cell. Examples of adhesives, include those classes and examples recited previously herein.

The present invention also relates to photovoltaic assemblies or modules that include two or more photovoltaic cells of the present invention. With a photovoltaic assembly or module, each photovoltaic cell thereof is electrically connected to at least one other photovoltaic cell thereof. With some embodiments of the photovoltaic assemblies of the present invention, at least one first photovoltaic cell is connected to a second photovoltaic cell by at least one electrical connector that is in electrical contact with: (i) the back electrode of the first photovoltaic cell; and (ii) the transparent conductive oxide coating of the second photovoltaic cell.

For purposes of non-limiting illustration and with reference to FIG. 3, photovoltaic module 4 includes two photovoltaic cells 1(a) and 1(b) according to the present invention. Photovoltaic cell 1(a) (which can be referred to as a first photovoltaic cell) and photovoltaic cell 1(b) (which can be referred to as a second photovoltaic cell) are electrically connected to each other. With further non-limiting reference to FIG. 3, back electrode 26 of photovoltaic cell 1(a) is electrically connected to transparent metal oxide coating 20 of photovoltaic cell 1(b) by a electrically conductive connector 62 that is in electrical contact therewith.

The photovoltaic cells of the present invention have reduced loss of incident light due to reflection compared to comparable photovoltaic cells that do not include the antireflective coating of the present invention. For purposes of non-limiting illustration, a comparable photovoltaic cell (that does not include the antireflective coating of the present invention) has a reflective loss of incident sunlight of at least 4%, such as from 4% to 10%. For purposes of further non-limiting illustration, photovoltaic cells according to the present invention have a reflective loss of incident sunlight of less than 4%, such as less than 3%, or less than 2%, or less than 1%, or less than 0.5%, or less than 0.25%, or less than 0.1%.

It will be readily appreciated by those skilled in the art that modifications can be made to the invention without departing from the concepts disclosed in the foregoing description. Accordingly, the particular embodiments described in detail herein are illustrative only and are not limiting to the scope of the invention, which is to be given the full breadth of the appended claims and any and all equivalents thereof.

What is claimed is:

1. A photovoltaic cell comprising:
(a) a transparent substrate comprising a first surface and a second surface, wherein said first surface and said second surface are opposed from each other;
(b) a transparent conductive oxide coating residing over said second surface of said transparent substrate;
(c) a photovoltaic coating residing over said transparent conductive oxide coating, said transparent conductive oxide coating being interposed between said second surface of said transparent substrate and said photovoltaic coating; and
(d) an antireflective coating over said first surface of said transparent substrate, wherein said antireflective coating comprises,
(i) a first layer comprising a metal oxide selected from an oxide of zinc, an oxide of zirconium, an oxide of tin, combinations of two or more thereof, and metal alloy oxides of two or more thereof, said first layer residing over said first surface of said transparent substrate,
(ii) a second layer comprising silica and optionally alumina, said second layer residing over said first layer,
(iii) a third layer comprising a metal oxide selected from an oxide of zinc, an oxide of zirconium, an oxide of tin, combinations of two or more thereof, and metal alloy oxides of two or more thereof, said third layer residing over said second layer, and
(iv) a fourth layer comprising silica and optionally alumina, said fourth layer residing over said third layer.

2. The photovoltaic cell of claim 1, wherein for said antireflective coating,
said first layer comprises zinc stannate,
said second layer comprises silica and aluminum oxide,
said third layer comprises zinc stannate, and
said fourth layer comprises silica.

3. The photovoltaic cell of claim 2, wherein for said antireflective coating,
said second layer comprises silica in an amount of from 70 percent by weight to 95 percent by weight, and aluminum oxide in an amount of from 5 percent by weight to 30 percent by weight, in each case based on total weight of said third layer.

4. The photovoltaic cell of claim 1, wherein for said antireflective coating,
said first layer has a thickness of from 15 nm to 22 nm,
said second layer has a thickness of from 22 nm to 33 nm,
said third layer has a thickness of from 95 nm to 143 nm, and
said fourth layer has a thickness of from 75 nm to 115 nm.

5. The photovoltaic cell of claim 1, wherein for said antireflective coating,
a ratio of thickness of said second layer to thickness of said first layer is from 1:1 to 2:1,
a ratio of thickness of said third layer to thickness of said first layer is from 6:1 to 7:1, and
a ratio of thickness of said fourth layer to thickness of said first layer is from 4.5:1 to 5.5:1.

6. The photovoltaic cell of claim 1, wherein said antireflective coating consists of said first layer, said second layer, said third layer, and said fourth layer, and
said first layer consists of zinc stannate,
said second layer consists of silica and aluminum oxide,
said third layer consists of zinc stannate, and
said fourth layer consists of silica.

7. The photovoltaic cell of claim 1, wherein said antireflective coating is formed by sputtering vacuum deposition.

8. The photovoltaic cell of claim 1, wherein said transparent conductive oxide coating comprises at least one layer, wherein each layer of said transparent conductive oxide coating independently comprises: at least one of an oxide, a nitride, a carbide, and an oxycarbide of silica; at least one of an oxide, a nitride, a carbide, and an oxycarbide of aluminum; at least one of an oxide, a nitride, a carbide, and an oxycarbide of zirconium; at least one of an oxide, a nitride, a carbide, and an oxycarbide of tin; at least one of an oxide, a nitride, a carbide, and an oxycarbide of indium; and combinations of two or more thereof.

9. The photovoltaic cell of claim 8, wherein said transparent conductive oxide coating comprises a first layer comprising at least one of indium tin oxide and tin oxide, and a second layer comprising tin oxide, wherein said first layer comprising at least one of indium tin oxide and tin oxide is interposed between said transparent substrate and said second layer comprising tin oxide.

10. The photovoltaic cell of claim 1, wherein said transparent conductive oxide coating is formed by chemical vapor deposition.

11. The photovoltaic cell of claim 1, wherein said photovoltaic coating comprises a first layer comprising an n-type material, and a second layer comprising a p-type material, wherein said first layer comprising said n-type material is interposed between said transparent conductive oxide coating and said second layer comprising said p-type material.

12. The photovoltaic cell of claim 11, wherein said first layer comprising said n-type material comprises cadmium sulfide, and said second layer comprising said p-type material comprises cadmium telluride.

13. The photovoltaic cell of claim 1, wherein said photovoltaic coating comprises at least one layer comprising silicon.

14. The photovoltaic cell of claim 13, wherein said photovoltaic coating comprises at least one layer comprising polycrystalline silicon.

15. The photovoltaic cell of claim 1, wherein said transparent substrate comprises an organic polymer, inorganic glass, and combinations thereof.

16. The photovoltaic cell of claim 1 further comprising a back electrode, said back electrode being positioned over said photovoltaic coating.

17. The photovoltaic cell of claim 16 further comprising a back substrate, said back substrate being positioned over said back electrode.
